(19) United States
(12) Patent Application Publication
(10) Pub. No.: US 2018/0011795 A1
(43) Pub. Date: Jan. 11, 2018

(54) INFORMATION PROCESSING APPARATUS AND CACHE INFORMATION OUTPUT METHOD

(71) Applicant: FUJITSU LIMITED, Kawasaki-shi (JP)

(72) Inventor: Yoshinori SUGISAKI, Mishima (JP)

(73) Assignee: FUJITSU LIMITED, Kawasaki-shi (JP)

(21) Appl. No.: 15/621,223

(22) Filed: Jun. 13, 2017

(30) Foreign Application Priority Data
Jul. 5, 2016 (JP) 2016-133402

(51) Int. Cl. H03M 13/03

(52) U.S. Cl. CPC G06F 12/0893; H03M 13/03; G06F 12/0802; G06F 12/1045; G06F 12/121

(57) ABSTRACT

An information processing apparatus includes a memory, and a processor coupled to the memory and configured to count first number indicating storing a plurality of arrays of data to each of cash lines, the data being accessed in accordance with execution of a program, and count second number indicating cache thrashing to the cache lines when the first number exceeds number of ways of cache.

### CROSS-REFERENCE TO RELATED APPLICATION

This application is based upon and claims the benefit of priority of the prior Japanese Patent Application No. 2016-133402, filed on Jul. 5, 2016, the entire contents of which are incorporated herein by reference.

### FIELD

The embodiments discussed herein are related to an information processing apparatus and a cache information output method.

### BACKGROUND

In recent years, researches have been in progress for high speed operation of a program (hereinafter referred to as an application program) running in a large-scale parallel computing system (hereinafter referred to as a high performance computing (HPC) system).

Specifically, as a method for operating an application program at a high speed in the HPC system, researches have been made, for example, on a solution to efficiently utilize caches of a central processing unit (CPU). In this case, researchers of the HPC system (hereinafter referred to merely as a researcher) operate an application program in the HPC system and thereby acquire information (hereinafter also referred to as profile data) including utilization statuses of caches (for example, cache L1 and cache L2) by the application program in operation. Then, the researcher seeks a solution to efficiently utilize the cache by, for example, analyzing the acquired profile data (for example, see Japanese Laid-open Patent Publication Nos. 2007-272691, 2003-323341, 10-187460, and 8-263372).

### SUMMARY

According to an aspect of the invention, an information processing apparatus includes a memory, and a processor coupled to the memory and configured to count first number indicating storing a plurality of arrays of data to each of cash lines, the data being accessed in accordance with execution of a program, and count second number indicating cache thrashing to the cache lines when the first number exceeds number of ways of cache.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of an information processing system;

FIG. 2 is a diagram illustrating a hardware configuration of an information processing apparatus;

FIG. 3 is a flowchart illustrating an overview of a cache information output processing in a first embodiment;

FIG. 4 is a flowchart illustrating a detail of the cache information output processing in the first embodiment;

FIG. 5 is a flowchart illustrating a detail of the cache information output processing in the first embodiment;

FIG. 6 is a flowchart illustrating a detail of the cache information output processing in the first embodiment;

FIG. 7 is a flowchart illustrating a detail of the cache information output processing in the first embodiment;

FIG. 8 illustrates a specific example of a source code of a verification target program;

FIG. 9 illustrates a specific example of the source code of the verification target program;

FIGS. 10A and 10B illustrate specific examples of information generated in the first embodiment;

FIGS. 11A and 11B illustrate specific examples of information generated in the first embodiment;

FIG. 12 illustrates a specific example of information generated in the first embodiment;

FIGS. 13A and 13B illustrate specific examples of information generated in the first embodiment;

FIGS. 14A and 14B illustrate specific examples of information generated in the first embodiment;

FIGS. 15A and 15B illustrate specific examples of information generated in the first embodiment;

FIG. 16 illustrates a specific example of information generated in the first embodiment;

FIGS. 17A and 17B illustrate specific examples of information generated in the first embodiment;

FIGS. 18A and 18B illustrate specific examples of information generated in the first embodiment;

FIGS. 19A and 19B illustrate specific examples of information generated in the first embodiment;

FIG. 20 illustrates a specific example of information generated in the first embodiment;

FIGS. 21A and 21B illustrate specific examples of information generated in the first embodiment;

FIGS. 22A and 22B illustrate specific examples of information generated in the first embodiment;

FIGS. 23A and 23B illustrate specific examples of information generated in the first embodiment;

FIG. 24 illustrates a specific example of information generated in the first embodiment; and

FIGS. 25A and 25B illustrate specific examples of information generated in the first embodiment.

### DESCRIPTION OF EMBODIMENTS

When analyzing profile data as described above, a researcher, for example, gets information of how many times cache thrashing (hereinafter merely referred to as thrashing) occurs in the cache. Then, in order to efficiently utilize the cache, the researcher seeks a solution to suppress the occurrence of thrashing in the cache.

Even by analysis of acquired profile data, however, the researcher may not identify a portion on a program (for example, sequence) that causes the thrashing in some cases. In this case, the researcher may not efficiently suppress the occurrence of the thrashing in the cache.

In view of the foregoing problem, it is an object of one aspect of the present embodiment to provide a cache information output program, a cache information output method, and an information processing apparatus which enable acquisition of information on a cache line where thrashing occurs during execution of a program.

[Configuration of Information Processing System]

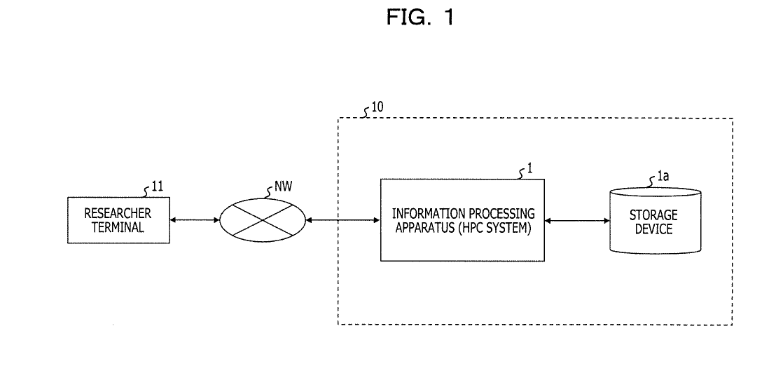

FIG. 1 is a diagram illustrating a configuration of an information processing system 10. The information processing system 10 illustrated in FIG. 1 includes an information processing apparatus 1 (hereinafter also referred to as a cache information output device 1), and a storage device 1a. The information processing apparatus 1 is capable of accessing a researcher terminal 11 via a network NW constituted by, for example, the Internet, an intranet, or the like.

The information processing apparatus 1 is, for example, a physical machine in which an HPC system is built, and executes an application program (hereinafter also referred to as a verification target program). Then, the information processing apparatus 1 implements a processing (hereinafter also referred to as a cache information output processing) that outputs information (hereinafter also referred to as line competition information) indicating how many times thrashing occurs during execution of the verification target program.

The storage device 1a is, for example, an external disk device including a hard disk drive (HDD) or a solid state drive (SSD). Specifically, the storage device 1a stores, for example, an execution file of the verification target program. The storage device 1a may be a disk device provided inside the information processing apparatus 1.

The researcher terminal 11 is, for example, a terminal through which an operator inputs requested information. Then, upon receiving input of the information by the operator, the researcher terminal 11 transmits, for example, the inputted information to the information processing apparatus 1.

[Method for Efficiently Utilizing Cache]

Next, a solution to efficiently utilize a cache in the CPU of the information processing apparatus 1 is described. The researcher, for example, causes the information processing apparatus 1 to execute the verification target program to acquire information (profile data) including a cache utilization status with execution of the verification target program. Then, the researcher seeks a solution to efficiently utilize the cache by, for example, analyzing acquired profile data.

When analyzing such profile data, the researcher, for example, gets information on how many times thrashing occurs in the cache. Then, in order to efficiently utilize the cache, the researcher seeks a solution to suppress the occurrence of thrashing in the cache.

Even by analyzing the acquired profile data, however, the researcher may fail to identify a portion on a program (for example, sequence) that causes thrashing. Thus, the researcher may not efficiently suppress the occurrence of thrashing in the cache.

To address the foregoing problems, the information processing apparatus 1 in the present embodiment makes comparison on cache lines which have stored the data of sequences accessed with execution of the verification target program. Thus, the information processing apparatus 1 determines whether there exists a cache line (hereinafter also referred to as a specific cache line) where the number of times the data of the sequence(s) has been stored (hereinafter also simply referred to as a sequence data storage count) with the execution of the verification target program is larger than a way number of the cache.

As a result, when determining that a specific cache line exists, the information processing apparatus 1 increments a counter indicating the number of occurrences of the cache thrashing in the specific cache line.

In other words, among the sequences contained in the verification target program, the researcher determines, in advance, one or more sequences, the data of which may cause thrashing by being accessed. Then, for each of the cache lines, the information processing apparatus 1 generates line competition information indicating the number of occurrences of thrashing in the cache line, by using the information indicating the cache lines which has stored the data of the sequences determined above, and information indicating the way number of the cache in the information processing apparatus 1.

Thus, by referring to the generated line competition information, the researcher may identify a cache line where the thrashing occurs, and a sequence that causes the thrashing. Therefore, the researcher may seek a solution to efficiently utilize the cache based on the identified information.

[Hardware Configuration of Information Processing Apparatus]

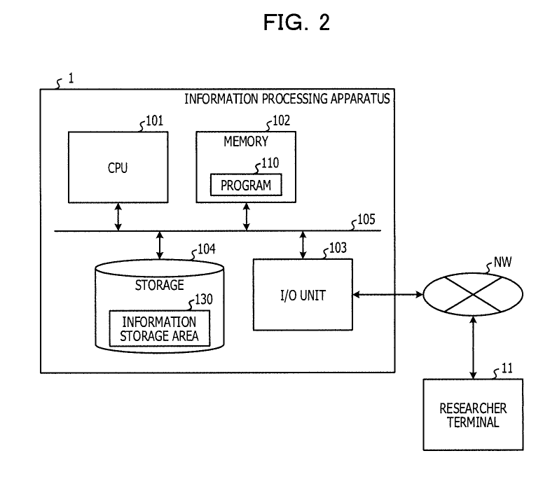

Next, a hardware configuration of the information processing apparatus 1 is described. FIG. 2 is a diagram illustrating a hardware configuration of the information processing apparatus 1.

The information processing apparatus 1 includes a CPU 101 being a processor, a memory 102, an external interface (I/O unit) 103, and a storage 104. These components are coupled with one another via a bus 105.

The storage 104 is configured to store a program 110 for implementing a cache information output processing into a program storage area (not illustrated) in the storage 104.

As illustrated in FIG. 2, the CPU 101 is configured to load the program 110 from the storage 104 into the memory 102 during execution of the program 110 and implement the cache information output processing in cooperation with the program 110. Specifically, the CPU 101 operates, in cooperation with the program 110, as an instruction adding unit configured to add an instruction to the verification target program, an area reserving unit for reserving an area for generation of the line competition information, and an information generation unit configured to generate the line competition information and so on. Also, the CPU 101 operates, in cooperation with the program 110, as an information output unit configured to output the line competition information and so on. The program 110 may be, for example, a program that functions as a compiler compiling the verification target program.

The storage 104 includes, for example, an information storage area 130 (hereinafter also referred to as a storage unit 130) configured to store information that is referred to when implementing the cache information output processing. Specifically, the information storage area 130 stores, for example, an execution file of the verification target program. Further, the information storage area 130 stores information outputted by a cache output processing.

The external interface 103 communicates with the researcher terminal 11, or the like. The storage unit 1a illustrated in FIG. 1 may be a storage device corresponding to the storage 104.

[Overview of First Embodiment]

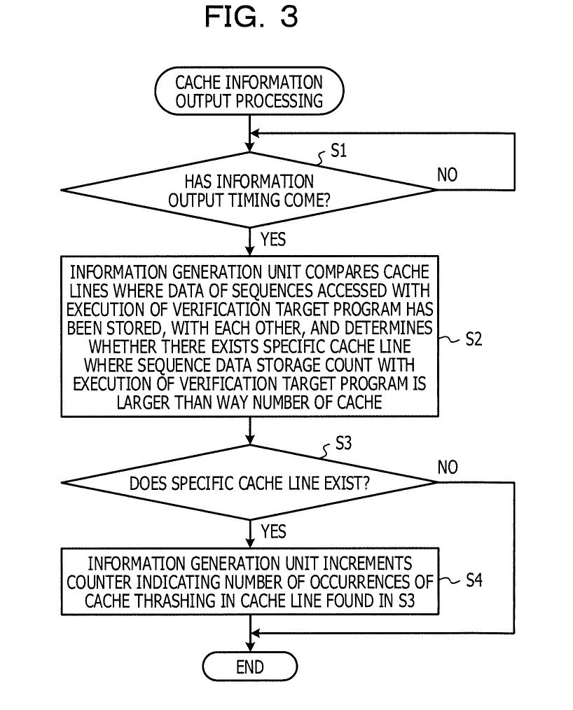

Next, an overview of the first embodiment is described. FIG. 3 is a flowchart illustrating an overview of a cache information output processing in the first embodiment.

The information generation unit of the information processing apparatus 1 stands by until an information output timing comes (S1: NO). The information output timing may be, for example, a timing when a program execution unit (not illustrated) of the information processing apparatus 1 executes the verification target program. Thereafter, when the information output timing comes (S1: YES), the information generation unit makes comparison on cache lines storing data of multiple sequences accessed with execution of the verification target program. Thus, the information generation unit determines whether there exists a specific cache line where the sequence data storage count with the execution of the verification target program is larger than the way number of the cache (S2).

Specifically, among the multiple sequences contained in the verification target program, the researcher, for example, determines in advance one or more sequences, the data of which may cause thrashing by being accessed. Then, the information processing apparatus 1 determines whether there exists a cache line in which the thrashing has occurred due to access to the data of the sequences determined above by the researcher.

Next, when determining that there exists a specific cache line where the sequence data storage count is larger than the way number of the cache (S3: YES), the information generation unit increments a counter indicating the number of occurrences of the cache thrashing in a specific cache line (S4). On the other hand, when determining that there does not exist a specific cache line where the sequence data storage count is larger than the way number of the cache (S3: NO), the information generation unit skips the processing of the step S4.

Namely, when the determined multiple sequences are sequences contained in an instruction (hereinafter referred to as a specific instruction) enclosed by a loop instruction in a source code of the verification target program, data of the multiple sequences is accessed every time a processing by the loop instruction is iterated. For this reason, every time a specific instruction is executed, the information generation unit determines whether there exists a specific cache line. Then, the information generation unit increments a counter for the specific cache line every time it determines that the specific cache line exists. Thus, the information generation unit may calculate information (line competition information) on the number of occurrences of the thrashing for each of cache lines.

Thus, the information processing apparatus 1 according to the present embodiment makes comparison on cache lines which have stored data of multiple sequences accessed with execution of the verification target program. Thus, the information processing apparatus 1 determines whether there exists a specific cache line where the sequence data storage count with execution of the verification target program is larger than the way number of the cache.

Consequently, when determining that the specific cache line exists, the information processing apparatus 1 increments a counter indicating the number of occurrences of the cache thrashing in the specific cache line.

Thus, by referring to the generated line competition information, the researcher may identify a cache line where the thrashing occurs, and a sequence that causes the thrashing. Therefore, the researcher may seek a solution to efficiently utilize the cache based on the identified information.

[Detail of First Embodiment]

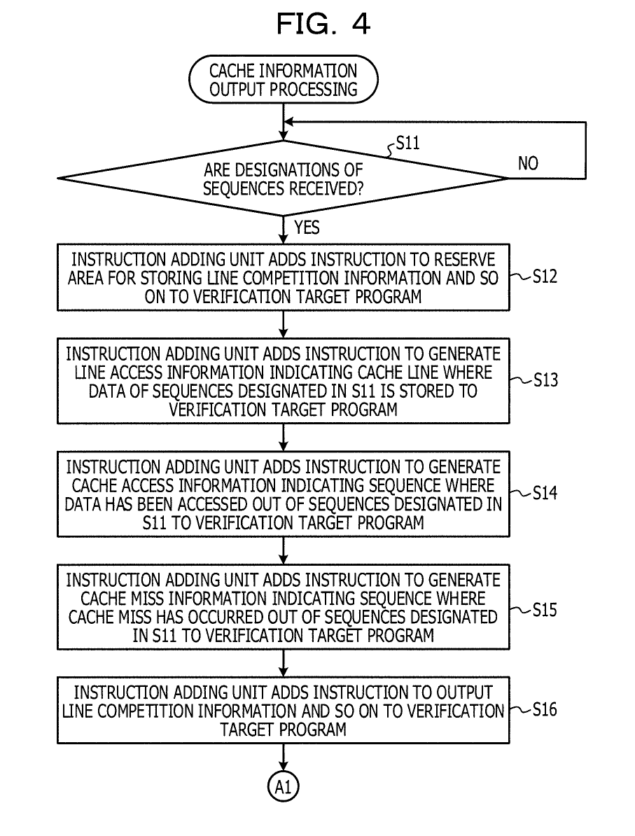

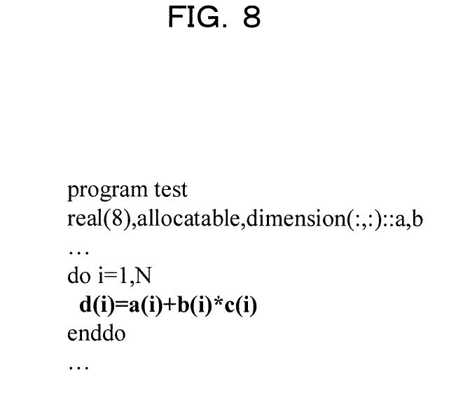

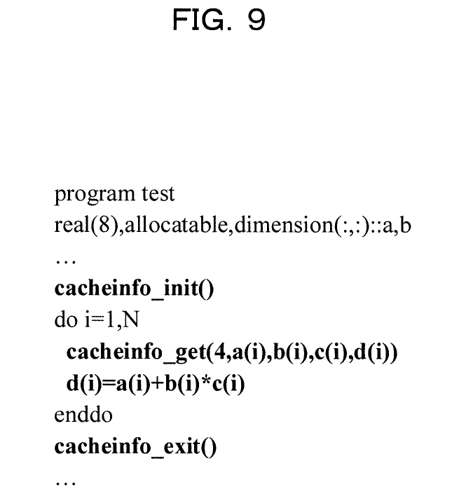

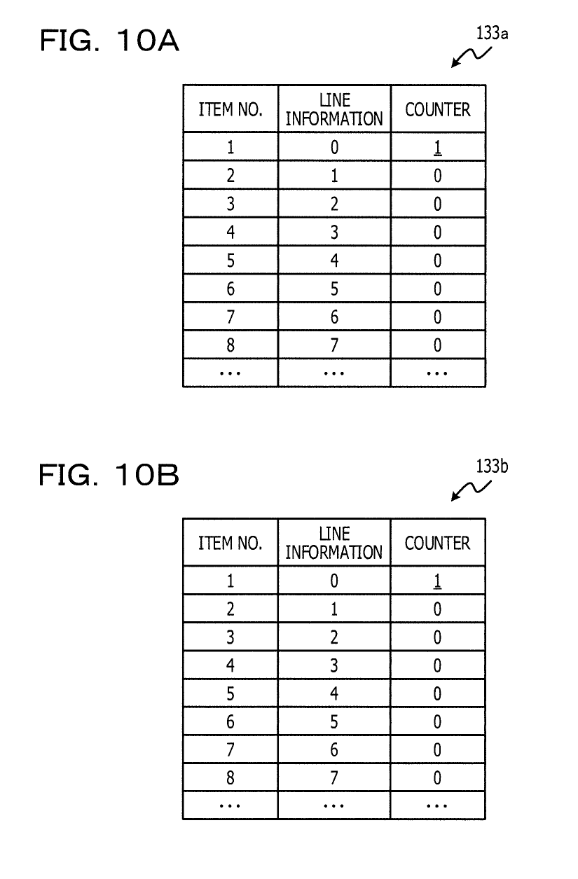

Next, detail of the first embodiment is described. FIGS. 4 to 7 are flowcharts illustrating details of a cache information output processing in the first embodiment. FIGS. 8 to 25B are diagrams illustrating details of the cache information output processing in the first embodiment. Specifically, FIGS. 8 and 9 illustrate specific examples of the source code of the verification target program. FIGS. 10A to 25B illustrate specific examples of information generated in the first embodiment. Hereinafter, flowcharts of FIGS. 4 to 7 are described with reference to FIGS. 8 to 25B.

The instruction adding unit of the information processing apparatus 1 stands by, for example, until receiving designations of multiple sequences by the researcher via the researcher terminal 11, as illustrated in FIG. 4 (S11: NO). Namely, the information processing apparatus 1 generates line competition information (hereinafter also referred to as line competition information 134) on the multiple sequences designated in the processing of S11, as described later.

Then, when the designations of the multiple sequences are received (S11: YES), the instruction adding unit adds an instruction to reserve an area for storing the line competition information 134 and so on to the verification target program (S12). In this case, the instruction adding unit adds an instruction to generate information (hereinafter also referred to as line access information 133) indicating a cache line in which data of the multiple sequences designated in the processing of S11 is stored, and an instruction to generate the line competition information 134 from the outputted line access information 133, to the verification target program (S13). In this case, the instruction adding unit adds an instruction to generate information (hereinafter also referred to as cache access information 131) indicating a sequence whose data is accessed, among the multiple sequences designated in the processing of S11, to the verification target program (S14). In this case, the instruction adding unit adds an instruction to generate information (hereinafter also referred to as cache miss information 132) indicating a sequence in which a cache miss occurs, among the multiple sequences designated in the processing of S11, to the verification target program (S15). Further, in this case, the instruction adding unit adds an instruction to output the generated line competition information 134 and so on, to the verification target program (S16). Hereinafter, specific examples of processings of S12 to S16 are described.

[Specific Examples of Source Code of Verification Target Program]

FIG. 8 illustrates a specific example of the source code of the verification target program before processings of S12 to S16. FIG. 9 illustrates a specific example of the source code of the verification target program after processings of S12 to S16. Below description is based on the assumption that a sequence a, a sequence b, a sequence c, and a sequence d have been designated in the processing of S11.

Specifically, “d(i)=a(i)+b(i)×c(i)” being an instruction (specific instruction) of setting the sum of a product of the sequence b and the sequence c plus the sequence a to the sequence d when a variable i is incremented from 1 to N is stated in the source code of the verification target program illustrated in FIG. 8.

On the other hand, “cacheinfo_init( )” (hereinafter also referred to as an area reservation instruction) being an instruction to invoke an instruction to reserve an area for storing the line competition information 134 and so on prior to a loop instruction enclosing “d(i)=a(i)+b(i)×c(i)” is stated in the source code of the verification target program illustrated in FIG. 9. Namely, the area reservation instruction is equivalent to an instruction added in the processing of S12.

Also, “cacheinfo_get (4, a(i), b(i), c(i), d(i))” (hereinafter also referred to as an information generation instruction) being an instruction to invoke an instruction to generate the line competition information 134 and so on of four sequences (sequence a, sequence b, sequence c, and sequence d) before “d(i)=a(i)+b(i)×c(i)” is stated in the source code of the verification target program illustrated in FIG. 9. Namely, the information generation instruction is equivalent to an instruction added in processings of S13 to S15.

Further, “cacheinfo_exit( )” (hereinafter also referred to as an information output instruction) being an instruction to invoke an instruction to output (for example, storing the line competition information 134 and so on into the information storage area 130) the line competition information 134 and so on after a loop instruction enclosing “d(i)=a(i)+b(i)×c(i)” is stated in the source code of the verification target program illustrated in FIG. 9. Namely, the information output instruction is equivalent to an instruction added in the processing of S16.

In the source code of the verification target program illustrated in FIG. 9, “cacheinfo_init( )” and “cacheinfo_exit( )” are stated before and after the portion enclosed by the loop instruction. Thus, “cacheinfo_init( )” and “cacheinfo_exit( )” are both executed just one time. On the other hand, “cacheinfo_get (4, a(i), b(i), c(i), d(i))” is stated in the portion enclosed by the loop instruction along with a specific instruction in the source code of the verification target program illustrated in FIG. 9. Thus, “cacheinfo_get (4, a(i), b(i), c(i), d(i))” is executed at the same timing as the specific instruction. Then, “cacheinfo_get (4, a(i), b(i), c(i), d(i))” is executed the number of iterations of the processing by the loop instruction.

Below description is based on the assumption that the area reserving unit, the information generation unit, and the information output unit are invoked respectively by execution of the area reservation instruction, the information generation instruction, and the information output instruction. Hereinafter, “cacheinfo_init( )”, “cacheinfo_get (4, a(i), b(i), c(i), d(i))”, and “cacheinfo_exit( )” are collectively referred to merely as an added instruction.

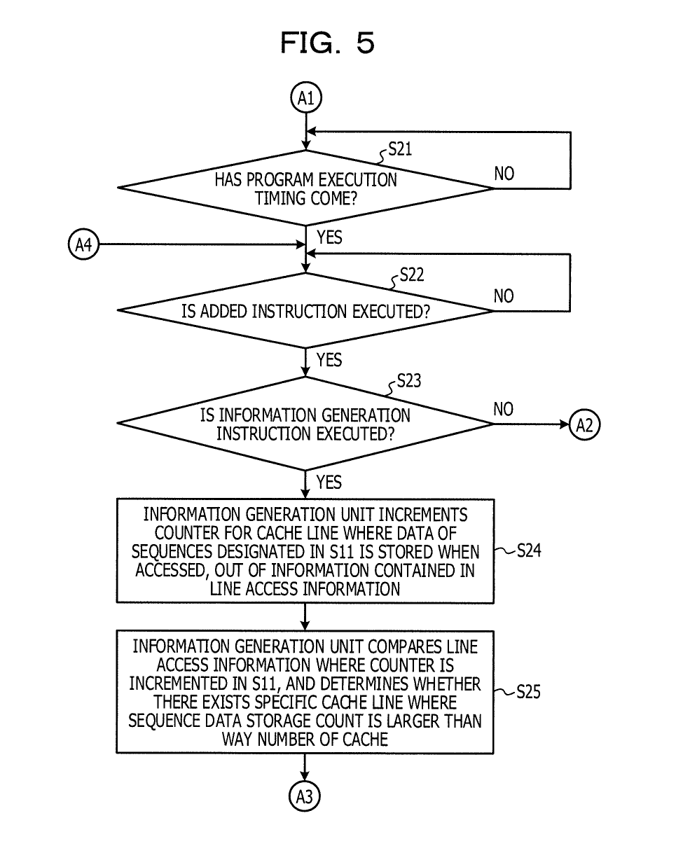

Referring back to FIG. 5, the information generation unit stands by until a program execution timing comes (S21: NO). The program execution timing may be, for example, a timing when execution of the verification target program is started. Processings following S21 are performed by execution of the verification target program to which an instruction is added in a processing of S11 to S16. Thus, processings following S21 may be performed by an information processing apparatus that is different from the information processing apparatus 1 in which processings of S11 to S16 are performed.

Thereafter, when the program execution timing comes (S21: YES), the information generation unit stands by until any one of added instructions is executed (S22: NO). Below description is based on the assumption that execution of the verification target program illustrated in FIG. 9 is started in the processing of S21. Also, below description is based on the assumption that a parameter variable N in the example illustrated in FIG. 9 is 128.

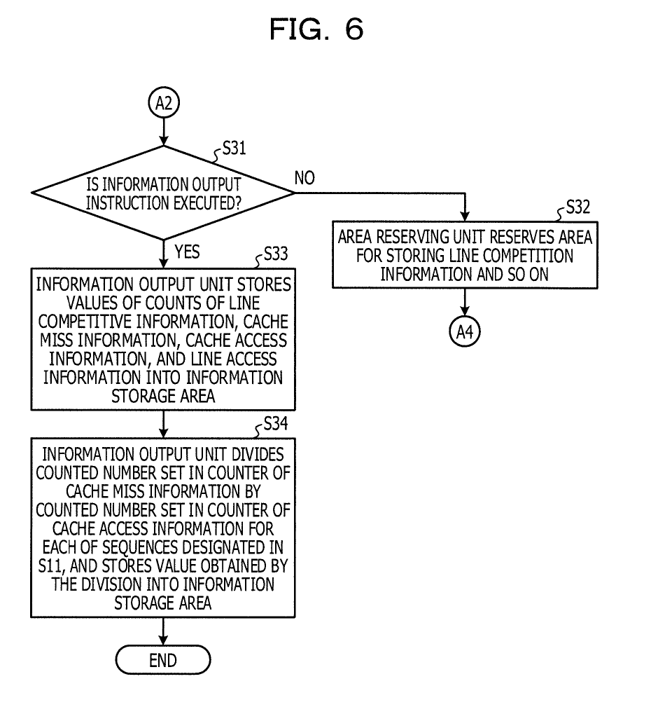

Then, when the area reservation instruction (“cacheinfo_init( )” in the example illustrated in FIG. 9) out of the added instructions is executed (S22: YES, S23: NO, S31: NO), the area reserving unit reserves an area for storing the line competition information 134 and so on in the information storage area 130 as illustrated in FIG. 6 (S32). Thereafter, the information generation unit stands by until an added instruction is executed again (S22: NO).

Next, when the information generation instruction (“cacheinfo_get (4, a(i), b(i), c(i), d(i))” in the example of illustrated in FIG. 9″) out of the added instructions is executed (S22: YES, S23: YES), the information generation unit generates (updates) the line access information 133. Specifically, the information generation unit increments a counter for a cache line where data of multiple sequences designated in the processing of S11 out of information contained in the line access information 133 is stored when accessed (S24). Namely, the information generation unit reflects, on the line access information 133, information related to an access by execution of a specific instruction along with the information generation instruction.

In this case, the information generation unit identifies, for example, a cache line where data of sequences (sequence a, sequence b, sequence c, and sequence d) contained in “cacheinfo_get (4, a(i), b(i), c(i), d(i))” in the example illustrated in FIG. 9 is stored. Then, the information generation unit generates the line access information 133 based on the identified information. Hereinafter, a specific example of identifying the cache line is described. Hereinafter, the CPU of the information processing apparatus 1 is assumed to have two (ways) of the cache with data capacity of 16 (KiB) per one (way). The cache of the CPU of the information processing apparatus 1 are assumed to have data capacity of 256 (B) per one (line). Further, data size for each sequence element in the caches of the CPU of the information processing apparatus 1 is assumed to be 8 (B).

[Specific Examples of Identifying Cache Line]

For example, in a case where an address in a cache where data for an element of the sequence a (hereinafter also simply referred to as data of sequence a(1)) is [0x00000] when the variable i is 1, a remainder of the division of [0x00000] by 16 (KiB) is [0x0]. Then, a quotient obtained by dividing [0x0] by 256 (B) is [0x0]. Thus, the information generation unit determines, for example, that the cache line where data of the sequence a(1) is stored is a 0th cache line.

In the same manner, in a case where an address in a cache where data of the sequence b(1) is stored is [0x08000], the information generation unit determines, for example, that the cache line where data of the sequence b(1) is stored is a 0th cache line. Further, in a case where an address in a cache where data of the sequence c(1) is stored is [0x10000], the information generation unit determines, for example, that the cache line where data of the sequence c(1) is stored is a 0th cache line.

On the other hand, in a case where an address in a cache where data of the sequence d(1) is stored is [0x14400], a remainder obtained by dividing [0x14400] by 16 (KiB) is [0x400]. Then, a quotient obtained by dividing [0x400] by 256 (B) is [0x4]. Thus, the information generation unit determines, for example, that a cache line where data of the sequence d(1) is stored is a 4th cache line. Hereinafter, a specific example of the line access information 133 after the processing of S24 is performed when the variable i is 1 is described.

[Specific Examples of Line Access Information (1)]

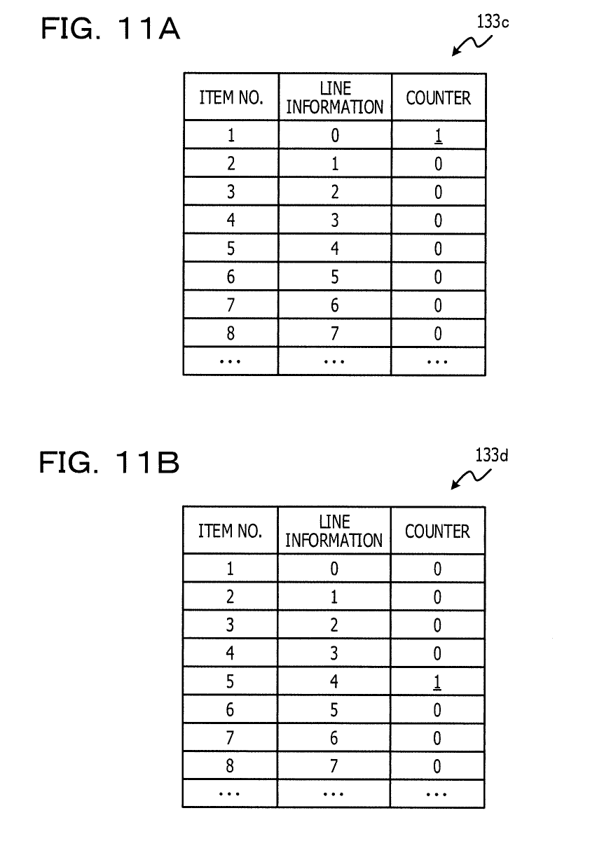

FIGS. 10A, 10B, 11A, 11B, 14A, 14B 15A, 15B, 18A, 18B, 19A, and 19B are diagrams illustrating specific examples of the line access information 133. Specifically, FIGS. 10A, 10B, 11A, and 11B are diagrams illustrating specific examples of the line access information 133 after the processing of S24 is performed when the variable i is 1. Further specifically, FIG. 10A is a diagram illustrating line access information 133a related to a cache line where data of the sequence a is stored when accessed, and FIG. 10B is a diagram illustrating line access information 133b related to a cache line where data of the sequence b is stored when accessed. FIG. 11A is a diagram illustrating line access information 133c related to a cache line stored when data of the sequence c is accessed, and FIG. 11B is a diagram illustrating line access information 133d related to a cache line where data of the sequence d is stored when accessed. Also, it is assumed that as a default value, “0” is set in all “counters” in advance. Hereinafter, the line access information 133a, line access information 133b, line access information 133c, and line access information 133d are collectively referred to as the line access information 133.

The line access information 133 illustrated in FIG. 10A and so on has, as fields, an “item number” identifying information contained in the line access information 133, “line information” in which a number identifying each cache line is set, and a “counter” in which the number of accesses to each cache line is set.

Specifically, as illustrated in FIG. 10A, when there is an access to data of the sequence a(1) stored in a cache line where “line information” is “0”, the information generation unit updates a value set in a “counter” of information in which “line information” is “0” to “1” (underlined portion of FIG. 10A). Also, as illustrated in FIG. 106, when there is an access to data of the sequence b(1) stored in the cache line where “line information” is “0”, the information generation unit updates a value set in the “counter” of information in which “line information” is “0” from “0” to “1” (underlined portion of FIG. 10B).

Further, as illustrated in FIG. 11A, when there is an access to data of the sequence c(1) stored in the cache line where “line information” is “0”, the information generation unit updates a value set in the “counter” of information in which “line information” is “0” from “0” to “1” (underlined portion of FIG. 11A). Also, as illustrated in FIG. 11B, when there is an access to data of the sequence d(1) stored in a cache line where “line information” is “4”, the information generation unit updates a value set in a “counter” of information in which “line information” is “4” from “0” to “1” (underlined portion of FIG. 11B).

Referring back to FIG. 5, the information generation unit makes comparison on line access information 133 in which the counter has been incremented in the processing of S24 (S25). Thus, the information generation unit determines whether there exists a specific cache line where the sequence data storage count with execution of the verification target program is larger than the way number of the cache of the CPU of the information processing apparatus 1 (S25). Namely, when there exists a cache line where the sequence data storage count is larger than the way number of the cache, the information generation unit determines that thrashing has occurred in a cache line that is determined to exist in the processing of S25 by execution of the verification target program.

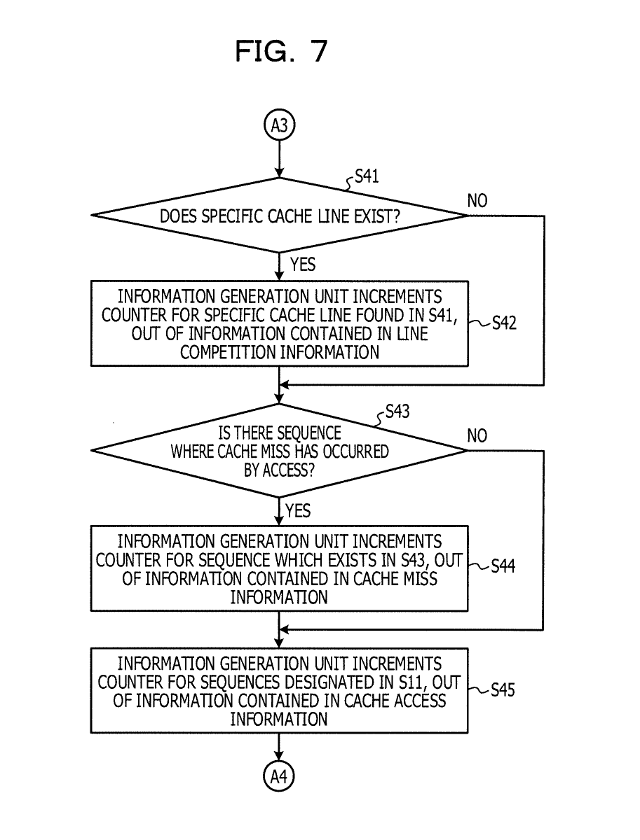

As a result, as illustrated in FIG. 7, when determining that a specific cache line exists (S41: YES), the information generation unit generates (updates) the line competition information 134. Specifically, the information generation unit increments a counter for a specific cache line that exists in the processing of S41, out of information contained in the line competition information 134 (S42). On the other hand, when determining that there does not exist a specific cache line (S41: NO), the information generation unit does not implement the processing of the step S42. Hereinafter, a specific example of the line competition information 134 after the processing of S42 is performed when the variable i is 1 is described.

[Specific Example of Line Competition Information (1)]

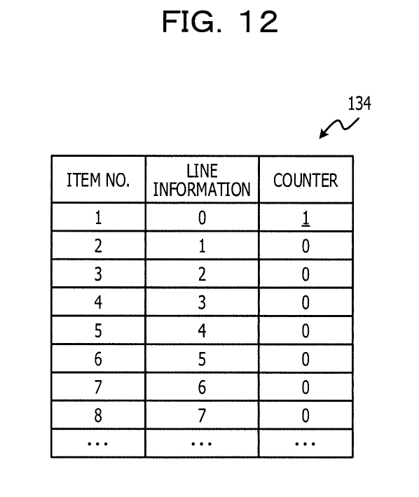

FIGS. 12, 16, 20, and 24 are diagrams illustrating specific examples of the line competition information 134. Specifically, FIG. 12 is a diagram illustrating a specific example of the line competition information 134 after the processing of S42 is performed when the variable i is 1.

The line competition information 134 illustrated in FIG. 12 and so on has, as fields, an “item number” identifying information contained in the line competition information 134, “line information” in which a number identifying each cache line is set, and a “counter” in which the number of occurrences of thrashing in each cache line is set. Also, it is assumed that as a default value, “0” is set in all “counters” in advance.

Specifically, in the line access information 133 illustrated in FIGS. 10A, 10B, 11A, and 11B, information for the sequence a, sequence b, and sequence c is updated out of information set in a “counter” of information in which “line information” is “0”. Thus, in this case, the information generation unit determines that data has been stored three times into the cache line where “line information” is “0”. Therefore, the information generation unit determines that the sequence data storage count in the cache line where “line information” is “0” is larger than 2 that is the way number of the cache.

Thus, in this case, the information generation unit determines that thrashing has occurred in the cache line where “line information” is “0”, and updates a value set in the “counter” of information where “line information” is “0” in the line competition information 134 from “0” to “1”, as illustrated in FIG. 12 (underlined portion of FIG. 12).

Referring back to FIG. 7, the information generation unit determines whether there exists a sequence where a cache miss has occurred by access to data (S43). Specifically, the information generation unit determines whether there exists a sequence (sequence where thrashing has occurred) where data is stored in a specific cache line existing in the processing of S41. Also, the information generation unit determines whether there exists a sequence where data is stored in a new cache line by execution of a specific instruction.

As a result, when determining that there exists a sequence where cache miss has occurred by access to data (S43: YES), the information generation unit generates (updates) cache miss information 132. Specifically, the information generation unit increments a counter for a sequence that exists in the processing of S43 out of information contained in the cache miss information 132 (S44). On the other hand, when determining that there does not exist a sequence where cache miss has occurred by access to data (S43: NO), the information generation unit does not perform the processing of S44. Hereinafter, a specific example of the cache miss information 132 after the processing of S44 is performed when the variable i is 1 is described.

[Specific Example of Cache Miss Information (1)]

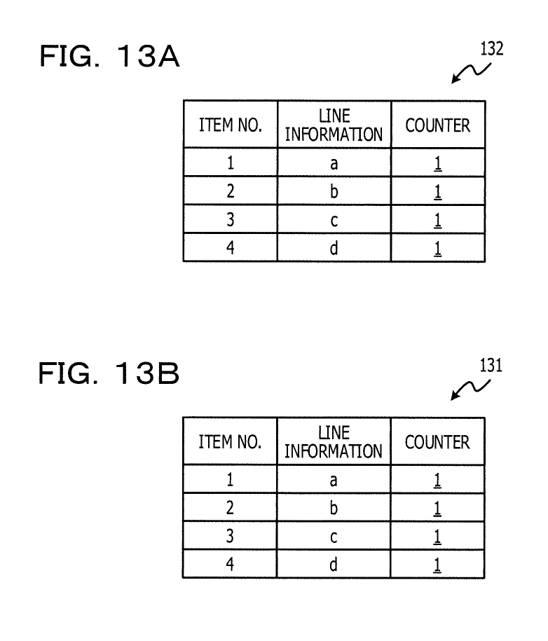

FIGS. 13A, 17A, 21A, and 25A are diagrams illustrating specific examples of the cache miss information 132. Specifically, FIG. 13A is a diagram illustrating a specific example of the cache miss information 132 after the processing of S44 is performed when the variable i is 1.

The cache miss information 132 illustrated in FIG. 13A and so on has, as fields, an “item number” identifying information contained in the cache miss information 132, “sequence information” identifying each sequence, and a “counter” in which the number of cache misses occurred by access to data of each sequence is set. In the cache miss information 132 illustrated in FIG. 13A, “a”, “b”, “c”, and “d”, which are set in the “sequence information”, correspond to the sequence a, sequence b, sequence c, and sequence d respectively. Also, it is assumed that as a default value, “0” is set in all “counters” in advance.

Specifically, in a case where data of the sequence a(1), sequence b(1), sequence c(1) or sequence d(1) is accessed when the variable i is 1, data of all the sequences is not stored into the cache. Thus, in this case, access to the data of the sequence a(1), sequence b(1), sequence c(1), and sequence d(1) causes the cache miss. Therefore, as illustrated in FIG. 13A, the information generation unit updates a value set in a “counter” of respective information from “0” to “1” (underlined portions of FIG. 13A).

Referring back to FIG. 7, the information generation unit generates (updates) cache access information 131. Specifically, the information generation unit increments counters for the multiple sequences designated in the processing of S11 out of information contained in the cache access information 131 (S45). Hereinafter, a specific example of the cache access information 131 after the processing of S45 is performed when the variable i is 1 is described.

[Specific Example of Cache Access Information (1)]

FIGS. 13B, 17B, 21B, and 25B are diagrams illustrating specific examples of the cache access information 131. Specifically, FIG. 13B is a diagram illustrating a specific example of the cache access information 131 after the processing of S45 is performed when the variable i is 1. The cache access information 131 illustrated in FIG. 13B and so on has, as fields, an “item number” identifying information contained in the cache access information 131, “sequence information” identifying each sequence, and a “counter” in which the number of accesses to each sequence is set. In the cache access information 131 illustrated in FIG. 13B, “a”, “b”, “c”, and “d”, which are set in the “sequence information”, correspond to the sequence a, sequence b, sequence c, and sequence d respectively. Also, it is assumed that as a default value, “0” is set in all “counters” in advance.

Specifically, as illustrated in FIG. 13B, when data of the sequence a(1), sequence b(1), sequence c(1), and sequence d(1) is accessed, the information generation unit updates the values set in “counters” of respective information from “0” to “1” (underlined portions of FIG. 13B).

Referring back to FIG. 7, the information generation unit stands by until an added instruction is executed again after the processing of S45 (S22: NO). Hereinafter, a specific example of the information where the variable i is 32 is described.

[Specific Example of Line Access Information (2)]

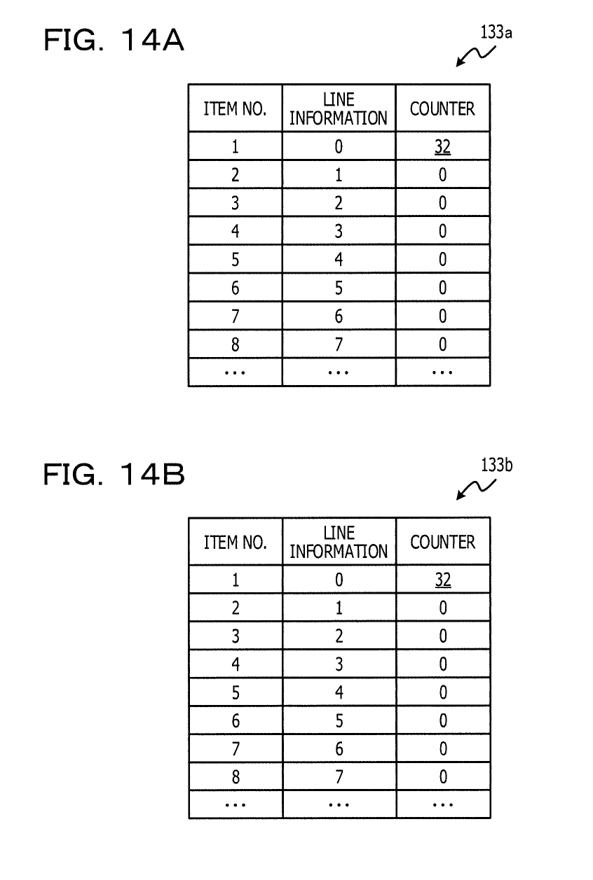

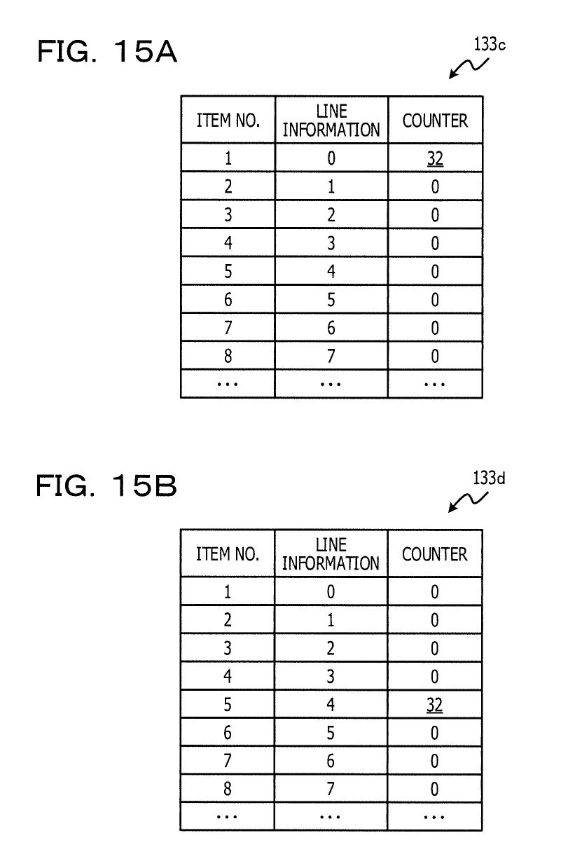

First, a specific example of the line access information 133 after the processing of S24 is performed when the variable i is 32 is described. FIGS. 14A, 14B, 15A, and 15B are diagrams illustrating specific examples of the line access information 133 after the processing of S24 is performed when the variable i is 32. FIGS. 14A, 14B, 15A, and 15B illustrate updated information illustrated in FIGS. 10A, 10B, 11A, and 11B respectively.

Specifically, as illustrated in FIG. 14A, when there is an access to data of a sequence a(32) stored in the cache line where “line information” is “0”, the information generation unit updates a value set in the “counter” of information in which “line information” is “0” from “31” to “32” (underlined portion of FIG. 14A). Also, as illustrated in FIG. 14B, when there is an access to data of a sequence b(32) stored in the cache line where “line information” is “0”, the information generation unit updates a value set in the “counter” of information in which “line information” is “0” from “31” to “32” (underlined portion of FIG. 14B).

Further, as illustrated in FIG. 15A, when there is an access to data of a sequence c(32) stored in the cache line where “line information” is “0”, the information generation unit updates a value set in the “counter” of information in which “line information” is “0” from “31” to “32” (underlined portion of FIG. 15A). Also, as illustrated in FIG. 15B, when there is an access to data of a sequence d(32) stored in the cache line where “line information” is “4”, the information generation unit updates a value set in the “counter” of information in which “line information” is “4” from “31” to “32” (underlined portion of FIG. 15B).

[Specific Example of Line Competition Information (2)]

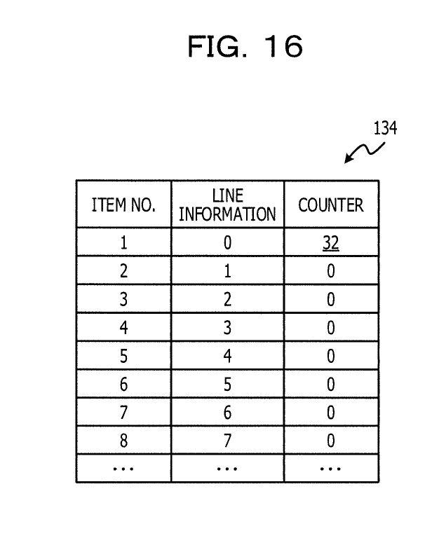

Next, a specific example of the line competition information 134 after the processing of S42 is performed when the variable i is 32 is described. FIG. 16 is a diagram illustrating a specific example of the line competition information 134 after the processing of S42 is performed when the variable i is 32.

Specifically, in the line access information 133 illustrated in FIGS. 14A, 14B, 15A, and 15B, information for the sequence a, sequence b, and sequence c out of information set in a “counter” of information in which “line information” is “0” is updated. Thus, in this case, the information generation unit determines that data has been stored three times into the cache line where “line information” is “0”. Therefore, the information generation unit determines that the sequence data storage count in the cache line where “line information” is “0” is larger than 2 that is the way number of the cache.

Thus, in this case, the information generation unit determines that thrashing has occurred in the cache line where “line information” is “0”, and updates a value set in the “counter” of information where “line information” is “0” in the line competition information 134 from “31” to “32”, as illustrated in FIG. 16 (underlined portion of FIG. 16).

[Specific Example of Cache Miss Information (2)]

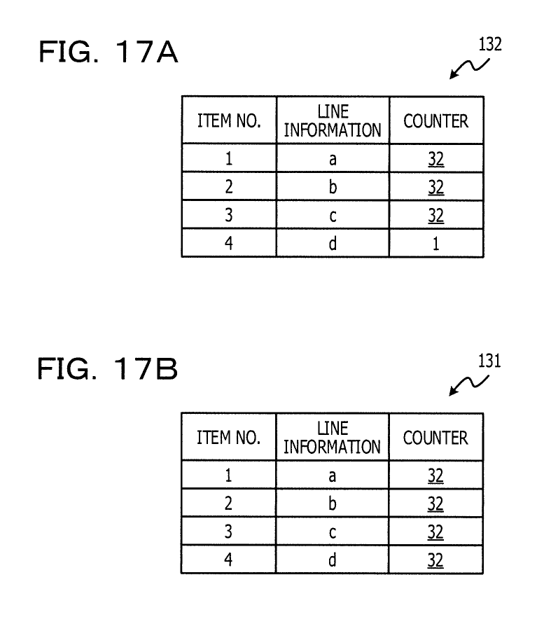

Next, a specific example of the line competition information 134 after the processing of S44 is performed when the variable i is 32 is described. FIG. 17A is a diagram illustrating a specific example of the cache miss information 132 after the processing of S44 is performed when the variable i is 32.

In the verification target program illustrated in FIG. 9, in a case where a specific instruction is executed when the variable i is in a range between 2 and 31, thrashing in a relationship among the sequence a, sequence b, and sequence c occurs in the cache line where “line information” is “0”. Thus, when data of the sequence a(32) is accessed, data of the sequence b or sequence c may be stored in the cache line where “line information” is “0”. Therefore, in this case, the information generation unit determines that there is a possibility that a cache miss occurs in the cache line where “line information” is “0”.

Thus, as illustrated in FIG. 17A, the information generation unit updates a value set in the “counter” of information where “sequence information” is “a”, “b”, and “c” from “31” to “32” (underlined portions of FIG. 17A).

On the other hand, in the verification target program illustrated in FIG. 9, in a case where a specific instruction is executed when the variable i is in a range between 2 and 31, thrashing does not occur in the cache line where “line information” is “4”. Thus, as illustrated in FIG. 17A, the information generation unit does not update a value set in the “counter” of information where “sequence information” is “d”.

[Specific Example of Cache Access Information (2)]

Next, a specific example of the cache access information 131 after the processing of S24 is performed when the variable i is 32 is described. FIG. 17B is a diagram illustrating a specific example of the cache access information 131 after the processing of S45 is performed when the variable i is 32.

Specifically, as illustrated in FIG. 17B, when data of the sequence a(32), sequence b(32), sequence c(32), and sequence d(32) is accessed, the information generation unit updates the values set in “counters” of respective information from “31” to “32” (underlined portions of 17B). Hereinafter, a specific example of the information where the variable i is 33 is described.

[Specific Example of Line Access Information (3)]

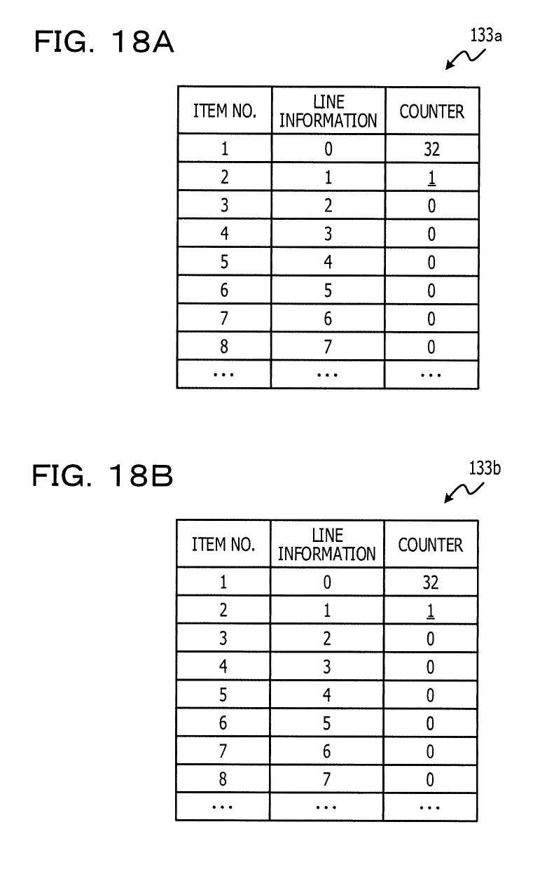

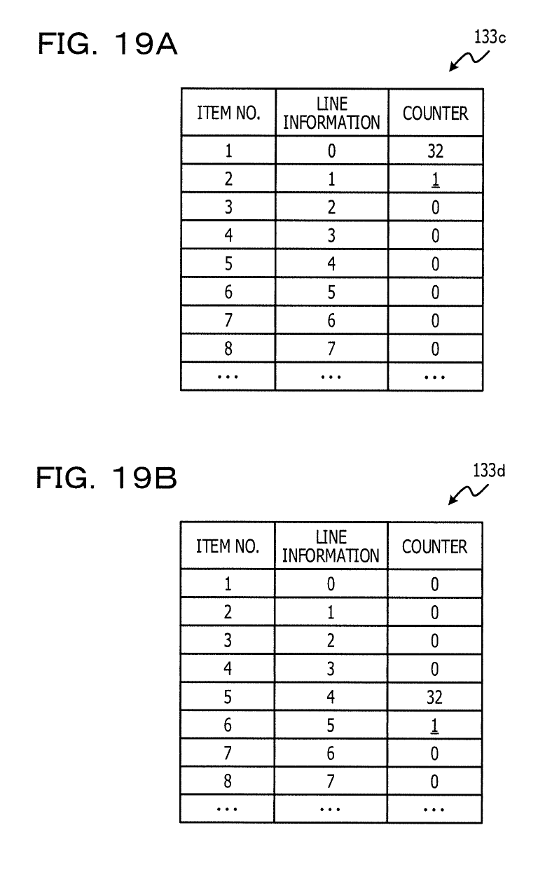

First, a specific example of the line access information 133 after the processing of S24 is performed when the variable i is 33 is described. FIGS. 18A, 18B, 19A, and 19B are diagrams illustrating specific examples of the line access information 133 after the processing of S24 is performed when the variable i is 33. FIGS. 18A, 18B, 19A, and 19B illustrate updated information illustrated in FIGS. 14A, 146, 15A, and 15B, respectively.

As described above, when data capacity per one (line) of the cache is 256 (B) and data size for each sequence element is 8 (B), data of 32 sequence elements may be stored in one (line) of the cache. Thus, 33th and subsequent data of the sequence a, sequence b, sequence c, and sequence d is stored in a cache line different from the cache line in which 1st to 32nd data is stored. Therefore, the data of the sequence a(33), sequence b(33), and sequence c(33) is stored into a cache line where “line information” is “1”, the cache line being next to the cache line where “line information” is “0”. The data of the sequence d(33) is stored into a cache line where “line information” is “5”, the cache line being next to the cache line where “line information” is “4”.

Then, as illustrated in FIG. 18A, when there is an access to data of the sequence a(33) stored in the cache line where “line information” is “1”, the information generation unit updates a value set in the “counter” of information where “line information” is “1” from “0” to “1” (underlined portion of FIG. 18A). Also, as illustrated in FIG. 18B, when there is an access to data of the sequence b(33) stored in the cache line where “line information” is “1”, the information generation unit updates a value set in the “counter” of information where “line information” is “1” from “0” to “1” (underlined portion of FIG. 18B).

Further, as illustrated in FIG. 19A, when there is an access to data of the sequence c(33) stored in the cache line where “line information” is “1”, the information generation unit updates a value set in the “counter” of information in which “line information” is “1” from “0” to “1” (underlined portion of FIG. 19A). Also, as illustrated in FIG. 19B, when there is an access to data of the sequence d(33) stored in a cache line where “line information” is “5”, the information generation unit updates a value set in a “counter” of information in which “line information” is “5” from “0” to “1” (underlined portion of FIG. 19B).

[Specific Example of Line Competition Information (3)]

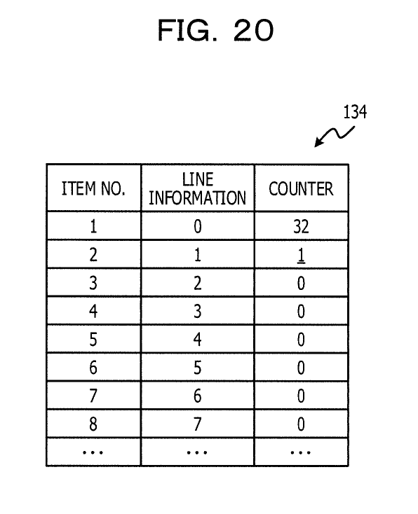

Next, a specific example of the line competition information 134 after the processing of S42 is performed when the variable i is 33 is described. FIG. 20 is a diagram illustrating a specific example of the line competition information 134 after the processing of S42 is performed when the variable i is 33.

Specifically, in the line access information 133 illustrated in FIGS. 18A, 18B, 19A, and 19B, information for the sequence a, sequence b, and sequence c out of information set in a “counter” of information in which “line information” is “1” is updated. Thus, in this case, the information generation unit determines that data has been stored three times into a cache line where “line information” is “1”. Therefore, the information generation unit determines that the sequence data storage count in the cache line where “line information” is “1” is larger than 2 that is the way number of the cache.

Thus, in this case, the information generation unit determines that thrashing has occurred in the cache line where “line information” is “1”, and updates a value set in the “counter” of information where “line information” is “1” in the line competition information 134 from “0” to “1”, as illustrated in FIG. 20 (underlined portion of FIG. 20).

[Specific Example of Cache Miss Information (3)]

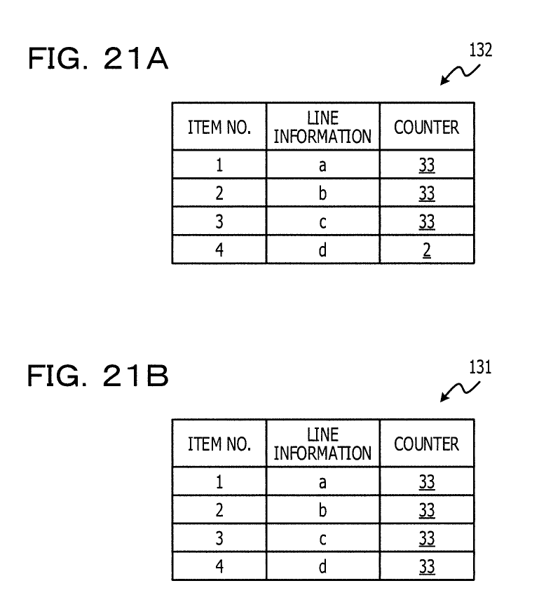

Next, a specific example of the cache miss information 132 after the processing of S44 is performed when the variable i is 33 is described. FIG. 21A is a diagram illustrating a specific example of the cache miss information 132 after the processing of S44 is performed when the variable i is 33.

Specifically, in a case where data of the sequence a(33), sequence b(33), sequence c(33), and sequence d(33) is accessed when the variable i is 33, data of respective sequences is not stored in the cache. Thus, in this case, access to data of the sequence a(33), sequence b(33), sequence c(33), and sequence d(33) causes the cache miss. Therefore, as illustrated in FIG. 21A, the information generation unit updates a value set in the “counter” of information where “sequence information” is “a”, “b”, and “c” from “32” to “33” (underlined portions of FIG. 21A). Also, as illustrated in FIG. 21A, the information generation unit updates a value set in the “counter” of information where “sequence information” is “d” from “1” to “2” (underlined portions of FIG. 21A).

[Specific Example of Cache Access Information (3)]

Next, a specific example of the cache access information 131 after the processing of S45 is performed when the variable i is 33 is described. FIG. 21B is a diagram illustrating a specific example of the cache access information 131 after the processing of S45 is performed when the variable i is 33.

Specifically, as illustrated in FIG. 21B, when data of the sequence a(33), sequence b(33), sequence c(33), and sequence d(33) is accessed, the information generation unit updates the values set in “counters” of respective information from “32” to “33” (underlined portions of FIG. 21B). Hereinafter, a specific example of the information where the variable i is 128 is described.

[Specific Example of Line Access Information (4)]

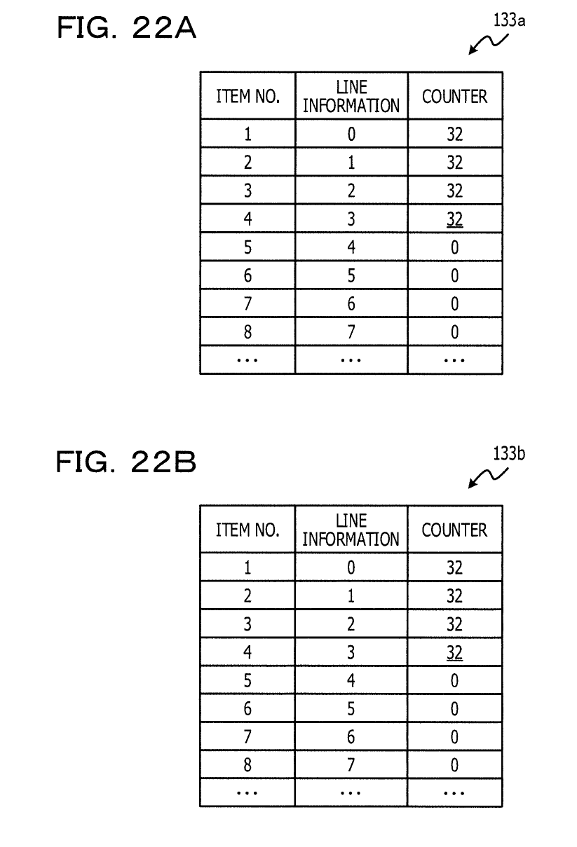

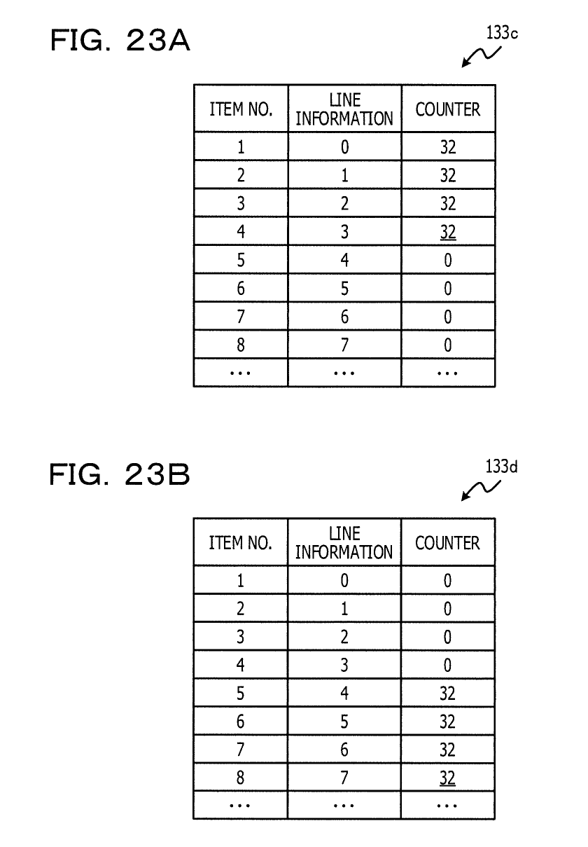

First, a specific example of the line access information 133 after the processing of S24 is performed when the variable i is 128 is described. FIGS. 22A, 22B, 23A, and 23B are diagrams illustrating specific examples of the line access information 133 after the processing of S24 is performed when the variable i is 128. FIGS. 22A, 22B, 23A, and 23B illustrate updated information illustrated in FIGS. 18A, 18B, 19A, and 19B, respectively.

Specifically, as illustrated in FIG. 22A, when there is an access to data of a sequence a(128) stored in a cache line where “line information” is “3”, the information generation unit updates a value set in a “counter” of information in which “line information” is “3” from “31” to “32” (underlined portion of FIG. 22A). Also, as illustrated in FIG. 22B, when there is an access to data of a sequence b(128) stored in a cache line where “line information” is “3”, the information generation unit updates a value set in a “counter” of information in which “line information” is “3” from “31” to “32” (underlined portion of FIG. 22B).

Further, as illustrated in FIG. 23A, when there is an access to data of the sequence c(128) stored in a cache line where “line information” is “3”, the information generation unit updates a value set in a “counter” of information in which “line information” is “3” from “31” to “32” (underlined portion of FIG. 23A). Also, as illustrated in FIG. 23B, when there is an access to data of a sequence d(128) stored in a cache line where “line information” is “7”, the information generation unit updates a value set in a “counter” of information in which “line information” is “7” from “31” to “32” (underlined portion of FIG. 23B).

[Specific Example of Line Competition Information (4)]

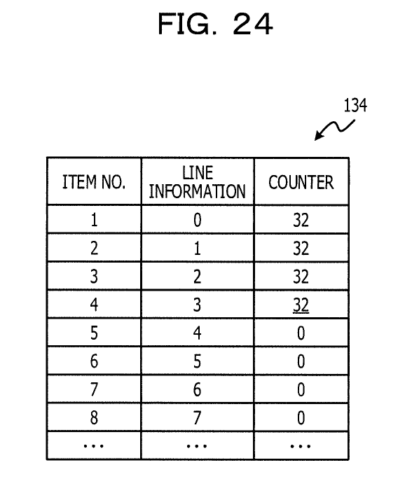

Next, a specific example of the line competition information 134 after the processing of S42 is performed when the variable i is 128 is described. FIG. 24 is a diagram illustrating a specific example of the line competition information 134 after the processing of S42 is performed when the variable i is 128.

Specifically, in the line access information 133 illustrated in FIGS. 22A, 22B, 23A, and 23B, information for the sequence a, sequence b, and sequence c out of information set in a “counter” of information in which “line information” is “3” is updated. Thus, in this case, the information generation unit determines that data has been stored three times into a cache line where “line information” is “3”. Therefore, the information generation unit determines that the sequence data storage count in a cache line where “line information” is “3” is larger than 2 that is the way number of the cache.

Thus, in this case, the information generation unit determines that thrashing has occurred in a cache line where “line information” is “3”, and updates a value set in the “counter” of information where “line information” is “3” in the line competition information 134 from “31” to “32”, as illustrated in FIG. 24 (underlined portion of FIG. 24).

[Specific Example of Cache Miss Information (4)]

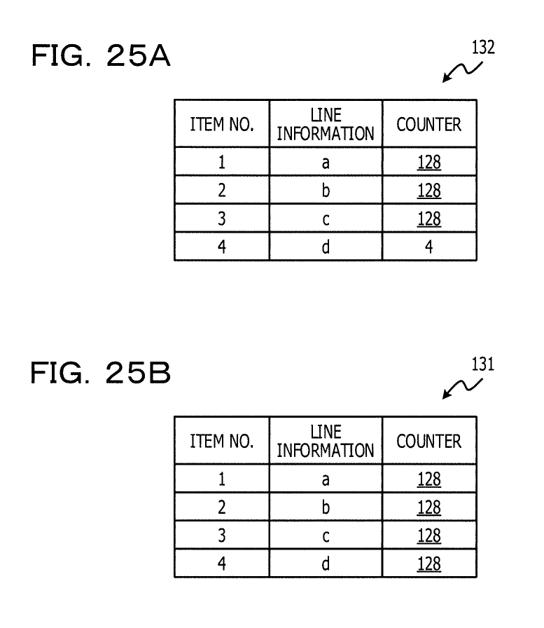

Next, a specific example of the line competition information 134 after the processing of S44 is performed when the variable i is 128 is described. FIG. 25A is a diagram illustrating a specific example of the cache miss information 132 after the processing of S44 is performed when the variable i is 128.

Specifically, in the same manner as illustrated in FIG. 17A, the information generation unit updates a value set in the “counter” of information where “sequence information” is “a”, “b”, and “c” as illustrated in FIG. 25A from “127” to “128” (underlined portions of FIG. 25A). In the same manner as illustrated in FIG. 17A, the information generation unit does not update the value set in the “counter” of information where “sequence information” is “d” as illustrated in FIG. 25A.

[Specific Example of Cache Access Information (4)]

Next, a specific example of the cache access information 131 after the processing of S45 is performed when the variable i is 128 is described. FIG. 25B is a diagram illustrating a specific example of the cache access information 131 after the processing of S45 is performed when the variable i is 128.

Specifically, as illustrated in FIG. 25B, when data of the sequence a(128), sequence b(128), sequence c(128), and sequence d(128) is accessed, the information generation unit updates the values set in “counters” of respective information from “127” to “128” (underlined portions of FIG. 25B).

Referring back to FIG. 5, when the information output instruction (in the example illustrated in FIG. 9, “cacheinfo_exit( )”) out of added instructions is executed (S22: YES, S23: NO, S31: YES), the information output unit of the information processing apparatus 1 stores the line competition information 134, cache miss information 132, cache access information 131, and line access information 133 into the information storage area 130 (S33). The information output unit may store, for example, only the count indicated by the counter of the line competition information 134 and so on into the information storage area 130.

Specifically, the information output unit may store the line access information 133 illustrated in FIGS. 22A, 226, 23A, and 23B, line competition information 134 illustrated in FIG. 24, cache miss information 132 illustrated in FIG. 25A, and cache access information 131 illustrated in FIG. 25B into the information storage area 130. Also, the information output unit may output the information stored in the information storage area 130 to an output device (not illustrated) of the researcher terminal 11.

Thus, the researcher may refer to information related to the thrashing and seek a solution to efficiently utilize the cache.

Specifically, the researcher, for example, refers to the line competition information 134 illustrated in FIG. 24, and determines that thrashing occurs in a cache line (cache line corresponding to information having a large value set in the “counter”) where “line information” is “0”, “1”, “2”, and “3”. Then, the researcher, for example, refers to the line access information 133 illustrated in FIGS. 22A, 22B, 23A, and 236, and determines that sequences stored in cache lines where “line information” is “0”, “1”, “2”, and “3” are the sequence a, sequence b, and sequence c. Further, the researcher, for example, refers to the cache miss information 132 illustrated in FIG. 25A, and determines that a cache miss has occurred by access to data of the sequence a, sequence b, and sequence c.

Thus, in this case, the researcher may, for example, determine that the thrashing, which has occurred in cache lines where “line information” is “0”, “1”, “2”, and “3”, is caused by access to data of the sequence a, sequence b, and sequence c.

The information output unit, for example, divides the counted number set in a counter of the cache miss information 132 by the counted number set in a counter of the cache access information 131 for each of the multiple sequences designated in the processing of S11, and stores a value obtained by the division into the information storage area 130 (S34).

Specifically, the information output unit divides a value “128” set in the “counter” of information for the sequence a in the cache miss information 132 illustrated in FIG. 25A by a value “128” set in the “counter” of information for the sequence a in the cache access information 131 illustrated in FIG. 25B, and multiplies a value obtained by the division by “100”. Then, the information output unit calculates “100%” being the calculated value as a cache miss ratio of the sequence a, and stores into the information storage area 130. In the same manner, the information output unit calculates “100%”, “100%”, and “3.12%” as cache miss ratios of the sequence b, sequence c, and sequence d respectively, and stores into the information storage area 130.

Thus, the researcher may seek a solution to efficiently utilize the cache.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing apparatus comprising:
a memory; and
a processor coupled to the memory and configured to:
count first number indicating storing a plurality of arrays of data to each of cash lines, the data being accessed in accordance with execution of a program; and
count second number indicating cache thrashing to the cache lines when the first number exceeds number of ways of cache.

2. The information processing apparatus according to claim 1, wherein
the plurality of arrays are contained in a predetermined instruction enclosed by a loop instruction in a source code of the program; and
the processor configured to count the second number in accordance with execution of the predetermined instruction.

3. The information processing apparatus according to claim 1, the processor further configured to select the plurality of arrays to be monitored before counting the first number.

4. The information processing apparatus according to claim 1, the processor further configured to output the second number after counting the second number.

5. The information processing apparatus according to claim 1, the processor further configured to:
output information indicating the cache line storing the plurality of arrays of data in accordance with execution of the program; and
judge an occurrence of the cache thrashing on the basis of the information indicating the cache line.

6. The information processing apparatus according to claim 1, the processor further configured to:
count third number indicating data of array is accessed in accordance with execution of the program;
count fourth number indicating occurrence of cache miss in accordance with execution of the program; and
output a difference between the third number and the second number for each of the plurality of arrays.

7. A cache information output method comprising:
counting, by a processor, first number indicating storing a plurality of arrays of data to each of cash lines, the data being accessed in accordance with execution of a program; and
counting, by a processor, second number indicating cache thrashing to the cache lines when the first number exceeds number of ways of cache.
